(19) United States
(12) Patent Application Publication
(10) Pub. No.: US 2008/0153256 A1
(43) Pub. Date: Jun. 26, 2008

(54) Methods and systems for nitridation of STI liner oxide in semiconductor devices

(75) Inventors: Hiroaki Niimi, Austin, TX (US); Manoj Mehrotra, Plano, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/644,339

(22) Filed: Dec. 22, 2006

(51) Int. Cl. H01L 21/76; C23C 16/513

(52) U.S. Cl. 438/439; 118/723 R; 257/E21.54

(57) ABSTRACT

The invention provides methods for forming isolation structures and STI trenches in a semiconductor device, which may be carried out in a variety of semiconductor manufacturing processes. One embodiment of the invention relates to a method of forming a semiconductor device having isolation structures. In this method, trench regions are formed within a semiconductor body, and then surfaces of the trench regions are nitrided. Then the nitrided surfaces are subjected to a condition that limits nitrogen desorption from the nitrided surfaces. The nitrided surfaces of the trench regions are then oxidized to form nitrogen containing liners, after which the isolation trench is filled with a dielectric material. Other methods and systems are also disclosed.

### FIELD OF INVENTION

The present invention relates generally to semiconductor devices and more particularly to methods and systems for forming shallow trench isolation structures in the manufacture of semiconductor devices.

### BACKGROUND OF THE INVENTION

In the area of semiconductor device fabrication, the metal-oxide-semiconductor (MOS) transistor is a basic building block, wherein the transistor can be controlled to operate either in a digital or analog manner. In the fabrication of MOS transistors, source and drain regions are doped opposite that of a body region or well region in a semiconductor substrate. For example, as illustrated in prior art FIG. 1, source/drain regions 12 are formed in a semiconductor body 14 of a MOS transistor, wherein the source/drain regions 12 are an n-type material and the body region 14 is a p-type material (an NMOS transistor). A gate structure 16, for example, a polysilicon gate electrode 18 overlying a gate dielectric 20, overlies a channel region 22 of the semiconductor body. Sidewall spacers 24 reside on lateral edges of the gate structure 16 to facilitate the spacing of extension regions 26 associated with the source/drains 12. Based on the gate structure 16, a distance between the source/drain regions 12 is defined, which is often referred to as a channel length “L”, while a depth of the transistor, or extent in which the transistor extends transverse to the channel, is often referred to as a width “W” of the device. The width-to-length ratio (W/L) is a factor that influences the drive current of the device, as well as other device performance characteristics.

As transistor devices are scaled down to improve device density, both the width “W” and the channel length “L” dimensions are reduced, giving rise to various fabrication and device performance issues. One problem associated with a reduction in the transistor width “W” is experienced when shallow trench isolation (STI) is employed for device isolation, and that problem is sometimes referred to as the inverse narrow width effect (INWE). As the transistor width is reduced the transistor drive current per unit width changes due to the edge effects that now play an appreciable role in transistor behavior. The gate dielectric thickness, its dielectric constant, and the channel orientation are different at the edges than at the planar center of the channel. The dopant concentration at the edges is different at than the center due to dopant segregation and STI stress induced diffusion at the interface. There is also the impact of STI and liner stress on the mobility near the edge of the channels. The STI edge may not be completely planar and may have a gate wrap around (more gate control) or less gate control depending upon the step height (difference between the top of the oxide over field and the top of the active regions). All these factors alter (raise or lower) threshold voltages of the narrow width device resulting in either reduction or increase in drive current per unit width. When the threshold voltage increases for narrow width devices and the drive current per unit width is reduced it results in weaker SRAM transistors which result in slower memory for example as well as functional problems for given SRAM designs. In such cases there is a need to improve the narrow width effects by mitigating the narrow width effects.

Therefore there is a need in the art for improved STI processes and techniques that reduce or alter the impact of the INWE in order to reduce or mitigate the device performance problems associated therewith.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The invention provides methods for forming isolation structures and STI trenches in a semiconductor device, which may be carried out in a variety of semiconductor manufacturing processes. One embodiment of the invention relates to a method of forming a semiconductor device having isolation structures. In this method, trench regions are formed within a semiconductor body, and then surfaces of the trench regions are nitrided. Then the nitrided surfaces are subjected to a condition that limits nitrogen desorption from the nitrided surfaces. The nitrided surfaces of the trench regions are then oxidized to form nitrogen containing liners, after which the isolation trench is filled with a dielectric material.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a prior art fragmentary perspective view of a MOS transistor.

FIGS. 2-8 are prior art partial side elevation views in section illustrating a conventional shallow trench isolation process for providing isolation between active areas in a semiconductor device.

FIG. 9 is a flow chart diagram illustrating a method for forming isolation structures in a semiconductor device in accordance with an aspect of the present invention.

FIGS. 10A to 10J are a plurality of diagrams illustrating a semiconductor device at various stages of fabrication in accordance with the method of FIG. 5.

FIG. 11 is a graph depicting an exemplary nitrogen concentration within a nitrogen containing liner as a function of time if the liner is not subject to a condition to prevent N₂ atoms from escaping the liner.

FIG. 12A-12C are embodiments of a cluster tool in accordance with aspects of the present invention.

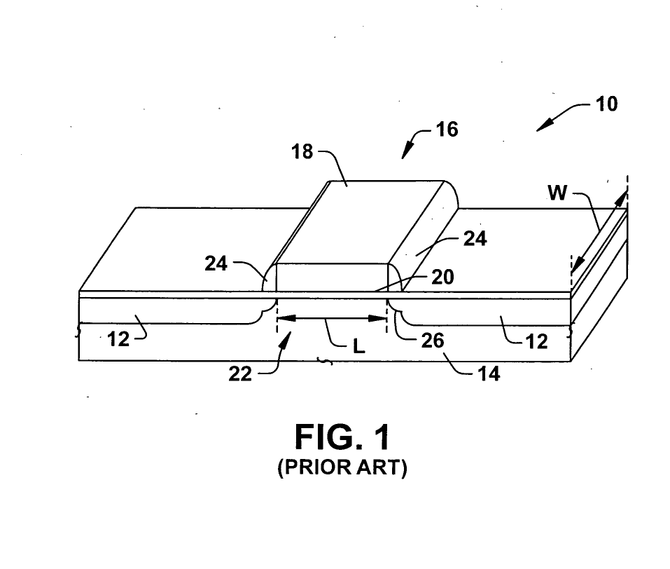

### DETAILED DESCRIPTION OF THE INVENTION

The present invention will now be described with reference to the attached drawings, wherein like reference numerals are used to refer to like elements throughout. The invention relates to methods for forming isolation structures and trenches in semiconductor devices, in which the negative impacts of the INWE are eliminated or substantially mitigated without the addition of extra mask steps. In addition, the method according to one exemplary aspect of the invention advantageously operates to improve a balance or minimize an imbalance of the threshold voltage performance of NMOS and PMOS transistors.

In order to fully appreciate the various aspects of the present invention, a brief description of a conventional STI fabrication process as appreciated by the inventors of the present invention will be discussed. After a discussion thereof, the various aspects of the present invention will be disclosed and more fully appreciated.

In the fabrication of semiconductor devices, isolation structures are formed between active areas in which electrical devices such as transistors, memory cells, or the like, are to be formed. The isolation structures, in this case shallow trench isolation (STI) structures, are typically formed during initial processing of a semiconductor substrate, prior to the formation of such electrical devices.

STI isolation techniques involve the formation of shallow trenches in the isolation areas or regions of a semiconductor wafer, which are subsequently filled with dielectric material such as silicon dioxide (SiO₂) to provide electrical isolation between devices subsequently formed in the active regions on either side of the filled trenches. A mask, such as a resist mask, is formed over the substrate surface and patterned to expose only the isolation regions, with the prospective active device regions covered. An anisotropic (e.g., “dry”) etch is then performed to form a trench through the substrate. Once the trench is etched, dielectric material is deposited to fill the trench with oxide. Thereafter, the device is commonly planarized using a chemical mechanical polishing (CMP) process.

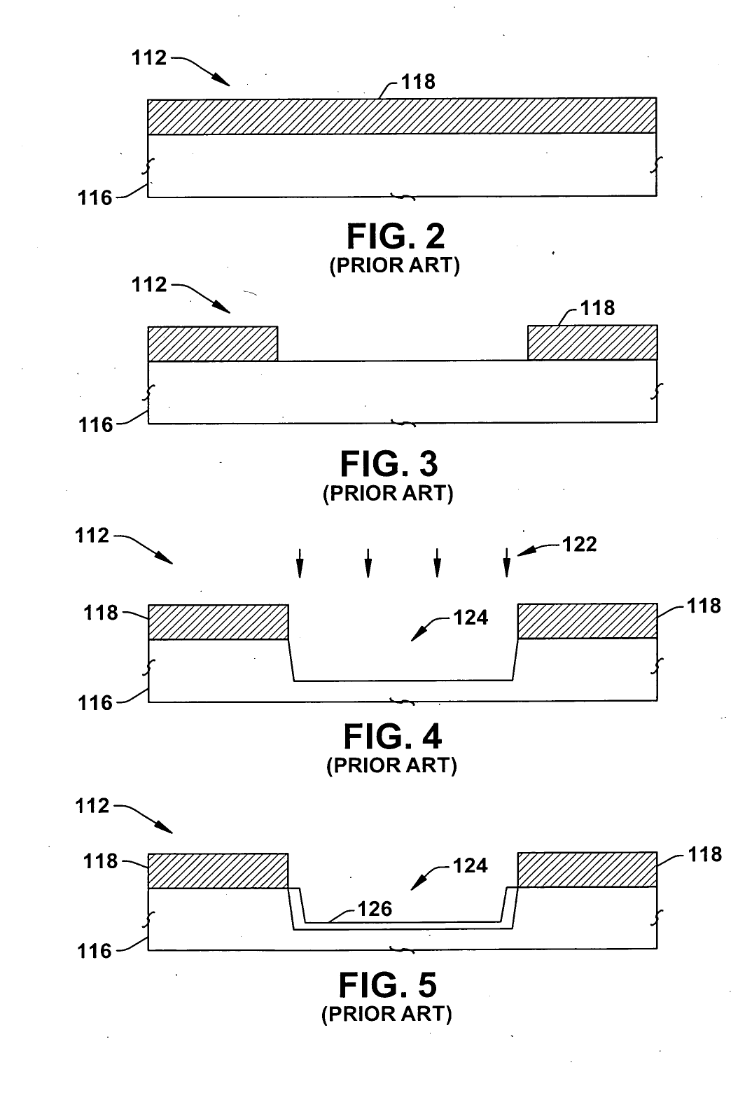

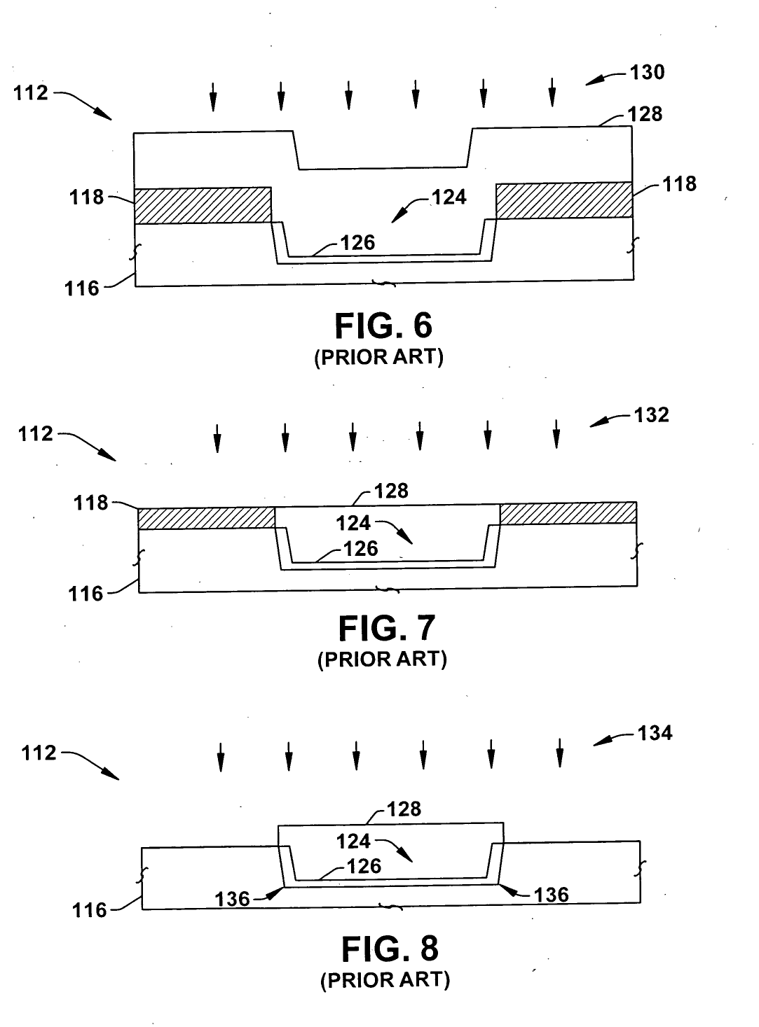

An example of a conventional STI process is illustrated in prior art FIGS. 6-12 to form trench isolation structures in a semiconductor device 112. In prior art FIG. 2, a mask 118 is formed over the device. The mask 118 is comprised of an etch resistant material such as silicon nitride or other suitable masking material. The mask is patterned in FIG. 3 to expose isolation regions of the device and cover active regions of the device. An etch 122 (e.g., a dry etch) is performed to form a trench 124 into the body region 116 as shown in FIG. 4. Subsequently, an oxide liner 126 is optionally formed in the trench 124 as shown in FIG. 5. The oxide liner 126 is formed by a thermal growth process.

Once the trench 124 and the liner 126 are formed, a dielectric material 128 is deposited in prior art FIG. 6 via a deposition process 130 to fill the trench 124 and also to cover the active regions of the device 112. In prior art FIG. 7, a chemical mechanical polishing (CMP) or other planarization process 132 is used to planarize the upper surface of the device 112, which exposes the remainder of the mask 118. Following planarization, the mask 118 is removed via a mask removal process 134 in prior art FIG. 8 to complete the isolation process, leaving the STI structure 128 in the trench 124.

The inventors of the present invention note that the conventionally formed STI structure 128 can lead to inverse width effects if the device 112 has a relatively small width dimension. These inverse width effects can degrade drive current, undesirably alter threshold voltages, and the like.

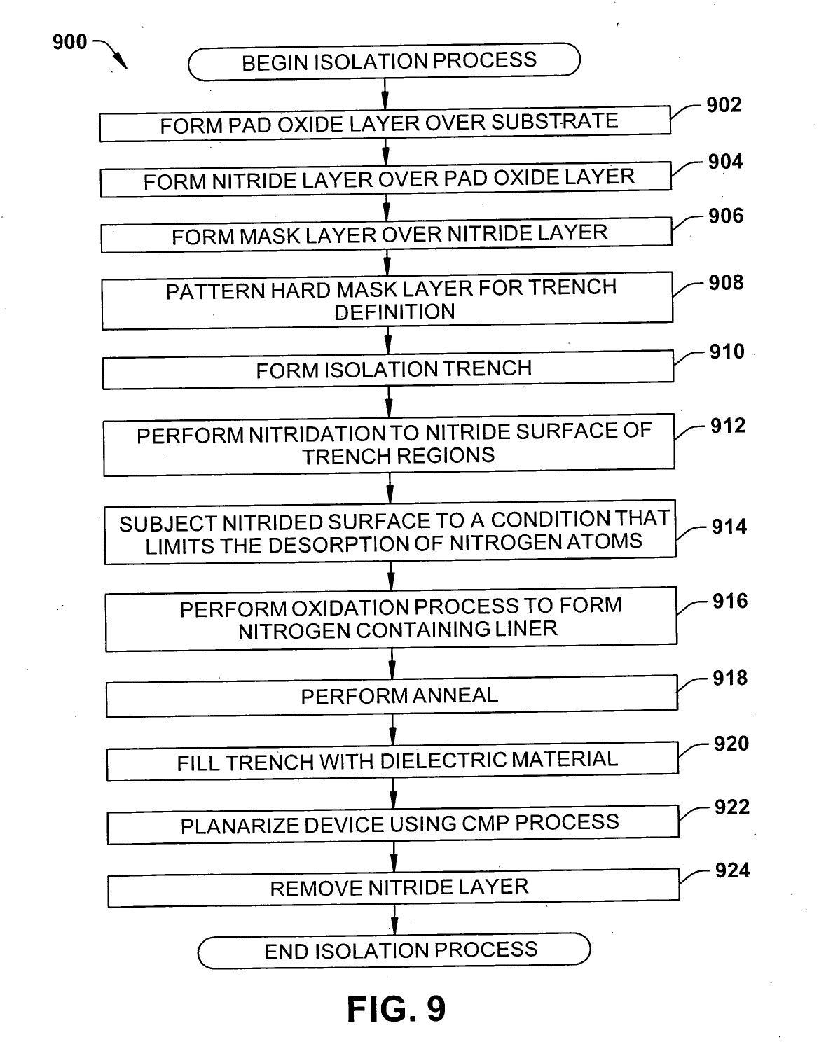

Referring now to FIG. 9, a flow diagram illustrating a method 900 for forming isolation structures in a semiconductor device in accordance with an aspect of the present invention is illustrated. While the method 900, and other methods according to the invention, are illustrated and described as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention.

Beginning at block 902, a hard mask layer is formed over a silicon semiconductor substrate or body of a semiconductor device. A relatively thin pad oxide layer may be formed on the semiconductor substrate prior to formation of the hard mask layer by thermally growing oxide. The hard mask is comprised of a suitable material, such as nitride (Si₃N₄) and is deposited, for example, by a low pressure chemical vapor deposition (LPCVD) or other suitable deposition process. The hard mask layer mitigates damage to active regions of the device during formation of isolation regions.

Continuing at block 904, a resist mask layer is formed over the device and on the hard mask layer that covers the active regions and exposes isolation regions. A photoresist material is deposited on the hard mask layer and patterned to expose the hard mask layer within the isolation regions and yet remain and cover the hard mask layer within the active regions.

The hard mask layer is then patterned using a suitable etch/patterning process and the resist mask layer as a mask at block 906 to expose underlying silicon of the isolation regions. The resist layer may then be removed by an ashing process. Subsequently, a trench formation process is performed at block 908 that etches the exposed portions of the silicon substrate to a selected depth, thereby forming trench regions. The etch process employed is typically selective to the material employed in the mask layer and etches into the semiconductor substrate within the exposed isolation regions so as to form the trench region having sidewalls, and a bottom. The width of the insulation trench is associated with the isolation opening(s) in the mask layer.

A number of suitable etch processes can be employed to form the trench regions at block 908. For example, a dry etch can be employed, which works well with hard mask layers. Additionally, reactive ion etching (RIE) can be employed. For example, a single or multi-step RIE etch process may be performed which removes material in the exposed isolation regions. Other suitable etch processes can also be employed.

At block 910, a nitridation process is performed that nitrides a surface of the sidewalls and bottom of the trench region. The nitridation doesn't necessarily form a nitride compound. A number of nitridation processes can be employed, such as plasma (non-thermal) nitridation. As an example, a suitable plasma nitridation process is performed using pulsed RF plasma with approximately 30-60% duty pulse with N₂ gas flow of approximately 100-700 sccm, pressure of approximately 5-30 mTorr for approximately 15-60 seconds.

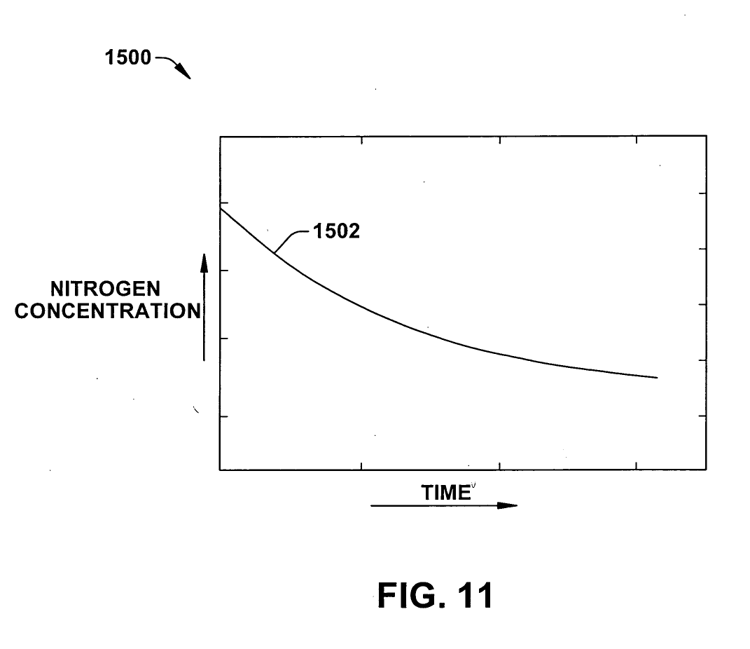

Because the plasma nitridation process may be intense, it can form a plasma damaged layer on the top of the nitrided surface. The plasma damaged layer is thermally unstable. Because of this thermal instability, air can reduce this layer at room temperature, which leads to nitrogen loss, absent countermeasures. In one embodiment (see FIG. 11, discussed infra), approximately 5 atomic % of nitrogen is lost after about 5 hours of exposure to air.

In order to combat this nitrogen loss, the nitrided surfaces are subjected to a condition to prevent the nitrogen atoms from desorbing from these nitrided surfaces at block 912. Thus, the nitrogen atoms that escape from the nitrided surface can be minimized or limited. The present invention extends to any condition by which the escape of nitrogen atoms from the nitrided surface could be minimized or limited, including but not limited to: an environmental condition, a voltage bias condition, a magnetic condition, a chemistry condition, or some other mechanism.

In one embodiment, the condition is an environmental condition such as a low O₂ environment, a high-vacuum environment, a low-vacuum environment, or a high N₂ environment, or some other environmental condition that prevents the nitrogen atoms from escaping from the nitrided surface.

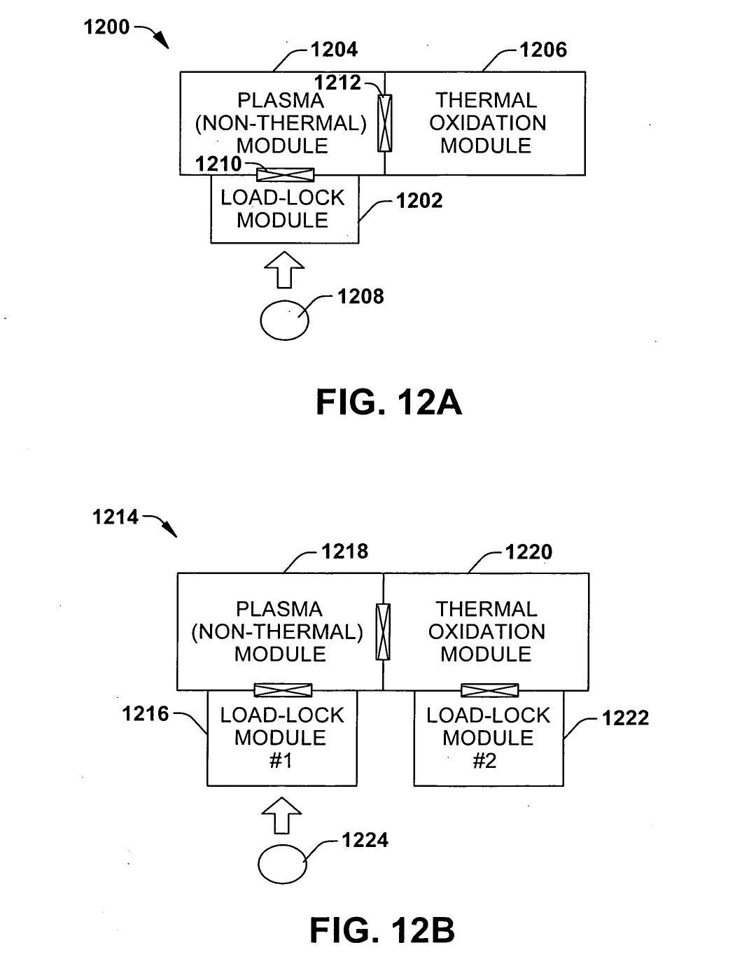

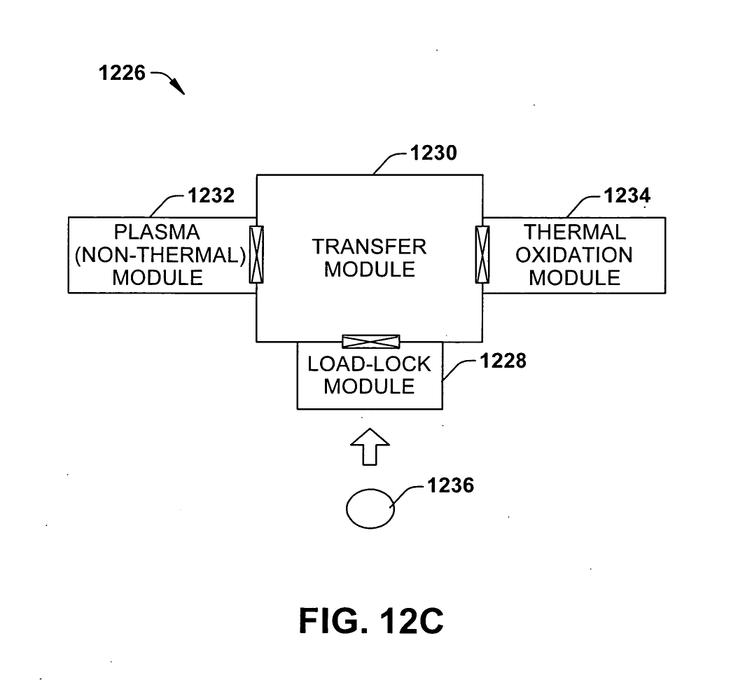

In various embodiments, this environmental condition can be achieved by using a “cluster” tool (see e.g., FIGS. 12A-12C, discussed infra), wherein the cluster too can control the environmental conditions to which the wafer is exposed and thereby prevent the wafer from being exposed to the environment external to the cluster tool (e.g., ambient laboratory environmental conditions). For example, one cluster tool could perform the nitridation process in block 910, then apply a condition such as a low O₂ environment to the wafer in block 912, and then perform the oxidation process in block 914. While performing these steps, the cluster tool could advantageously continuously isolate the wafer from the external or ambient laboratory environment. Other benefits of clustering include improved process control, increased throughput, and manufacturing friendliness (e.g., less sensitive time window between two processes).

After the condition is applied, an oxidation process is performed at block 914 that forms a nitrogen containing liner, such as nitrous oxide (N₂O), nitric oxide, or combination thereof liner. The oxidation process can be a thermal oxidation process and/or another suitable oxidation process. The concentration of nitrogen can vary throughout the nitride containing oxide liner layer. However, a nitrogen profile having a relatively higher nitrogen concentration near an interface between the silicon substrate and the liner can increasingly mitigate problems resulting from inverse width effects as one of benefits of the nitrided STI liner. As an example, N₂O oxidation could be done at approximately 1000-1150° C. at a pressure of 100-400 Torr for approximately 30-60 seconds under pure N₂O flow of approximately 9500 sccm.

It is noted that the inventors of the present invention contemplate alternate aspects of the invention that include other processes for forming nitrous oxide, nitric oxide, and other liners containing nitrogen. It is also noted the nitridation performed at block 910 prior to formation of the nitrogen containing liner at block 914 facilitates increasing the nitrogen composition at the silicon/liner interface.

Subsequently, an anneal is performed at block 916 after the formation of the nitrogen containing liner (e.g., nitrous oxide). The anneal serves to repair damage and/or mitigate uniformities within the trench region and the nitrogen containing liner layer.

At 918, the trench is filled with dielectric material such as SiO₂ or other electrically isolating material so as to provide electrical isolation between active regions on either side of the isolation trench. The trench filling operation at 918 may comprise forming or depositing dielectric material over the device to cover the hard mask layer in the active regions and to fill the trenches in the isolation regions thereof. The trench fill material may be deposited at 918 using any appropriate deposition techniques, for example, such as high density plasma (HDP) oxide deposition, low pressure chemical vapor deposition (LPCVD) employing a tetraethylorthosilicate (TEOS) gas, or plasma enhanced chemical vapor deposition (PECVD) of silicon dioxide from TEOS and oxygen mixtures (PETEOS).

The device is then planarized at 920 to expose a portion of the hard mask layer in the active regions, leaving a generally planar upper surface with portions of the nitride layer and a remaining portion of the fill material in the trench exposed. The remaining hard mask material is stripped or removed at 922, for example, using a wet etch process selective so as to remove hard mask material and to stop on or before the silicon substrate (e.g., a pad oxide layer can be employed) without damaging the underlying silicon or other semiconductor material in the active regions of the device. The isolation method 900 then ends. Thereafter, transistors, memory cells, and/or other electrical devices may be formed in the active regions using semiconductor processing techniques as are known.

The presence of nitrogen in the liner layer serves a number of purposes. The threshold voltages for relatively narrow width NMOS devices is generally reduced by the presence of nitrogen in the liner layer and the threshold voltages for relatively narrow PMOS devices is generally increased (decreased in magnitude) by the presence of nitrogen in the liner layer. Narrow width devices are typically defined as devices whose width is small enough that inverse width effects substantially deteriorate operation of the devices using conventional shallow trench isolation processing. Generally, narrow width devices of interest are under 200 nm in width.

The above alterations of threshold voltages facilitate improving drive current for transistor devices. For example, as a consequence, SRAM drive current over the SRAM load is increased thereby increasing the SRAM beta ration. The presence of nitrogen also reduces undesired diffusion of implanted source/drain dopants toward the surfaces of the active regions thereby preventing/mitigating the rise of threshold voltage for relatively narrow width devices.

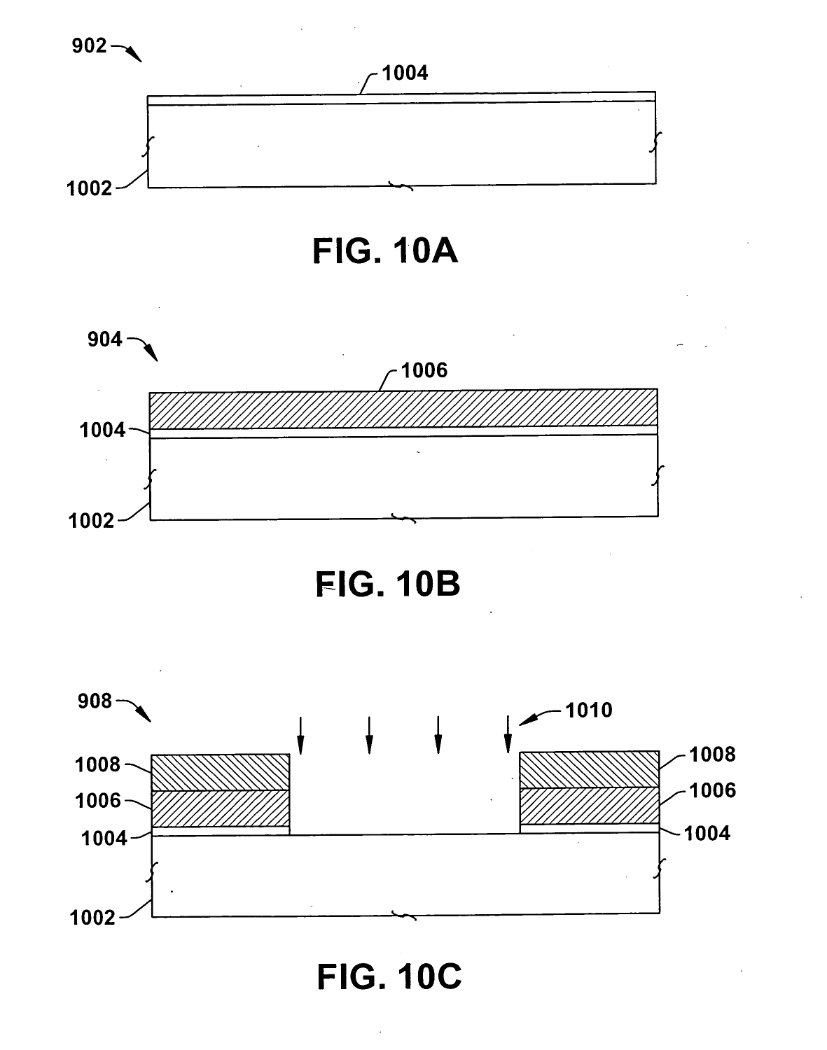

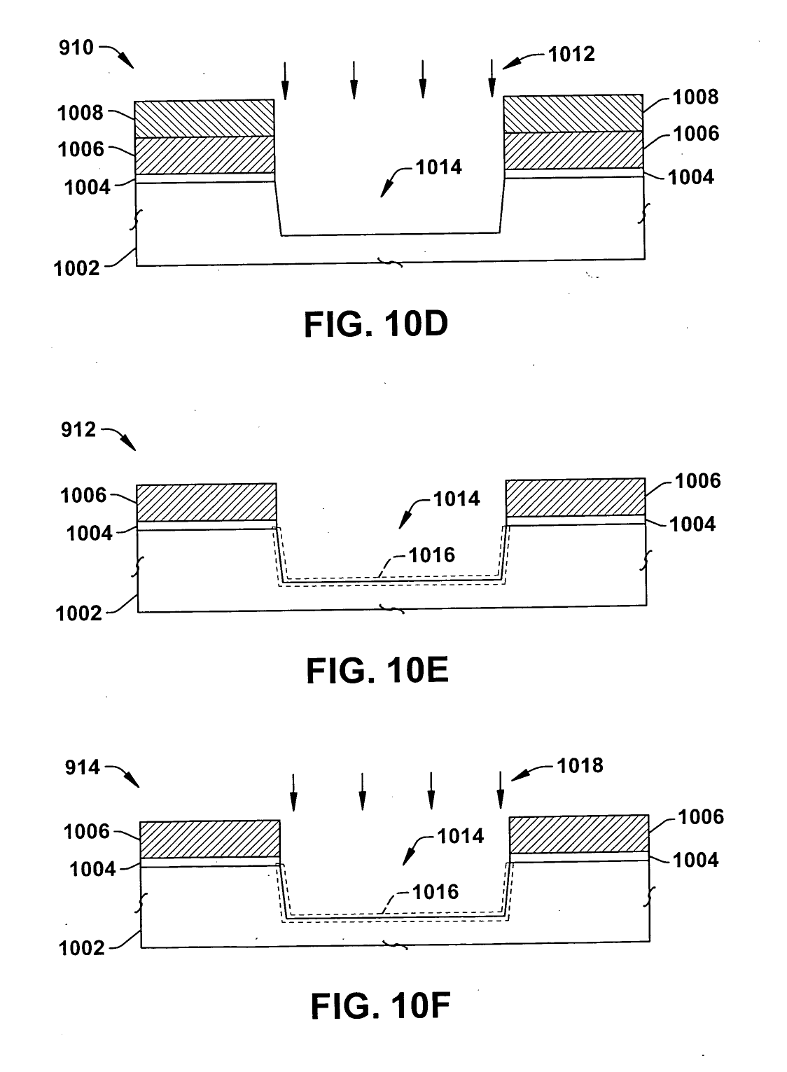

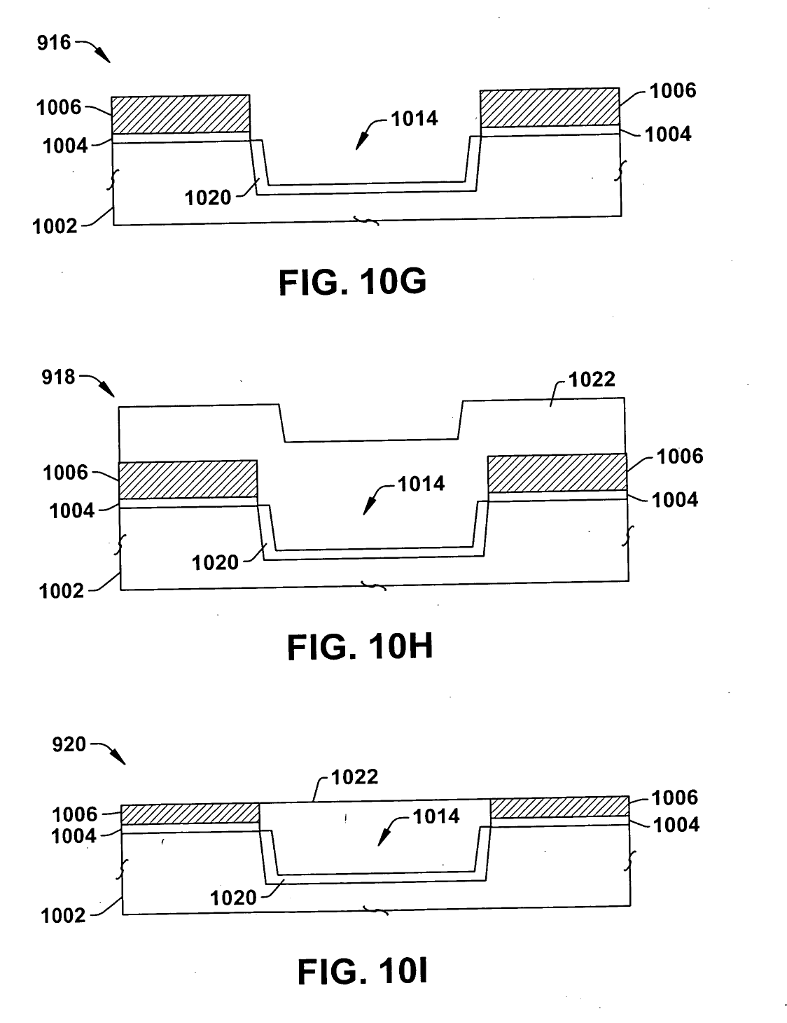

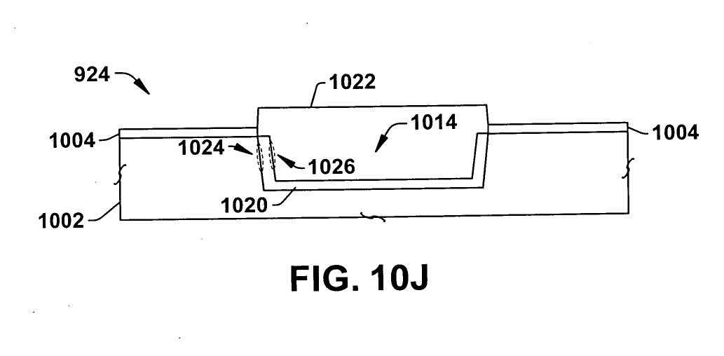

Referring now to FIGS. 10A to 10J, a semiconductor device is illustrated at various stages of fabrication in accordance with the exemplary method 900 of FIG. 9. The various stages of fabrication are exemplary in nature and are intended to facilitate a better understanding of the present invention. It is noted at this point that the illustrations provided herein are not necessarily drawn to scale, and that the above method 900 may be employed in processing structures other than those illustrated in the following figures, and further that the structures illustrated and described herein may be fabricated according to other techniques.

In FIG. 10A, the semiconductor device 1400 is illustrated comprising a semiconductor body (e.g., a substrate) 1002, such as silicon. An oxidation process (not shown) is initially employed to grow a pad oxide layer 1004 over the top surface of the substrate 1002 as illustrated in FIG. 10A.

FIG. 10B illustrates a hard mask layer 1006 formed on the pad oxide layer 1004 by depositing a hard mask material, such as silicon nitride. An exemplary process for forming the hard mask layer is a low pressure chemical vapor deposition (LPCVD).process of Si₃N₄ or equivalent nitride or equivalent material.

Thereafter, in FIG. 10C, a patterned mask 1008 (e.g., a developed photoresist) is formed to cover active regions of the device while exposing the hard mask layer 1006 in the isolation regions for subsequent trench formation therein. A dry etch process 1010 is employed in FIG. 10C, in one example, to etch through the hard mask layer 1006 and at least a portion of the pad oxide layer 1004 to substantially expose the semiconductor body associated with the isolation region. Alternatively, the etch process 1010 may etch only the hard mask layer 1006 and stop on the pad oxide layer 1004. In yet another alternative, the etch process 1010 may etch all of the exposed hard mask layer 1006 and the underlying pad oxide layer 1004 and land on the underlying semiconductor material. In another example, the etch process 1010 is employed to partially etch the hard mask layer 1006, wherein some portion of hard mask layer remains overlying the isolation regions. In one example, a remaining amount of the hard mask layer 1006 may be about 1,000 Angstroms thick, however, other remaining thicknesses are contemplated by the present invention.

Continuing with respect to FIG. 10D, an etch process 1012 is performed using the resist mask 1008 to form isolation trench regions 1014 to a depth and width in the isolation regions, where the trench regions comprises sidewalls and a bottom. Subsequently, the resist mask 1008 is removed by a suitable process, such as an ashing process.

A nitridation process is then performed that nitrides surfaces of the sidewalls and bottom of the trench regions 1014. Typically, a plasma nitridation process is employed. The nitridation process parameters, including source materials and duration, can be adjusted to obtain a desired nitridation of the surfaces. FIG. 10E depicts the semiconductor device 1400 after removal of the resist mask 1008 and performance of the nitridation process, and highlights nitrided surfaces 1016. The sidewalls of the oxide 1004 and mask layer 1006 may also be nitrided.

After the nitrided surfaces 1016 are formed, they are subjected to a condition to prevent the nitrogen atoms from desorbing from these nitrided surfaces in FIG. 10F. In one embodiment, the condition is an environmental condition 1018 such as a low O₂ environment, a high-vacuum environment, a low-vacuum environment, or a high N₂ environment, or some other environmental condition that prevents the nitrogen atoms from escaping from the nitrided surface until the oxidation process can be started.

Thereafter, an oxidation process is performed that forms a nitrogen containing liner 1020 on the sidewalls and bottom of the trench regions 1014 as shown in FIG. 10G. The liner can be formed by oxidation of the exposed portions of the trench 1014 using a thermal growth process. Such an oxidation process forms a nitrogen containing liner 1020 such as nitrous oxide, nitric oxide, and combinations thereof, with a varied nitrogen concentration profile. Subsequently, an anneal process is optionally performed that repairs damage incurred during the fill process.

The trench regions 1014 are then filled in with electrically isolating, dielectric material 1022 via a deposition process as shown in FIG. 10H. The process involves a suitable deposition methodology, such as depositing SiO₂ or other isolating material using a high density plasma (HDP) oxide deposition process, low pressure chemical vapor deposition (LPCVD) employing a tetraethylorthosilicate (TEOS) gas, or plasma enhanced chemical vapor deposition (PECVD) of silicon dioxide from TEOS and oxygen mixtures (PETEOS), although other fill materials and deposition processes are contemplated as falling within the scope of the present invention.

Continuing with FIG. 10I, a planarization process is performed to remove the upper portions of the fill material 1022 as well as upper portions of the hard mask layer 1006, wherein the hard mask layer 1006 serves as a planarization stop. The process can comprise a chemical-mechanical polishing (CMP) process wherein a generally planar upper surface is provided in the device 1400. Subsequently in FIG. 10J, the remainder of the hard mask layer 1006 is stripped or otherwise removed, leaving a finished STI isolation structure comprising the trench regions 1014 filled with dielectric material 1022 surrounded by a nitrogen containing line 1020 along sidewalls and bottoms of the trench regions 1014. A first interface 1024 is defined between the silicon material of the semiconductor body 1002 and the nitrogen containing liner 1020 and a second interface 1026 is defined between the nitrogen containing liner 1020 and the dielectric fill material 1022.

Thereafter, transistors, memory cells, and/or other electrical devices (not shown) may be formed in the active regions using semiconductor processing techniques as are known.

FIG. 11 is a graph 1100 depicting the effect on the liner if a condition is not applied to prevent the escape of nitrogen atoms from the nitrided layer as previously described (e.g., as described in FIG. 9, block 912). The graph 1100 shows a nitrogen concentration curve 1102 that relates to the first y-axis (“nitrogen concentration), and which shows the degradation of the nitrogen concentration of the liner layer in time. The graph 1100 also shows a thickness curve 1504 that relates to the second y-axis (“thickness”), and which shows the increasing thickness of the liner layer in time.

Thus, absent the application of the condition as set forth above, the nitrogen concentration of the liner will decrease as a function of time as shown by curve 1502. Note that the nitrogen concentration 1502 is representative of one depth or “slice” within the liner, and it will be appreciated that the nitrogen profile could vary over the depth of the liner and this “slice” of the profile is exemplary in nature.

Because the nitriding layer has advantageous properties and improves device characteristics and performance, it is desirable to keep the nitrogen concentration at relatively high levels. Further, as with any process step, it is desirable to retain precise control of the nitrogen concentration and thickness of the liner layer. Therefore, by applying the condition these undesirable effects may be limited or eliminated altogether.

Referring now to FIGS. 12A-12C, one can see one embodiment of various cluster tools in accordance with aspects of the present invention. In general, the cluster tools use two process modules for forming the nitrided STI, namely, a plasma/non-thermal nitridation tool and a thermal N₂O oxidation tool. These process modules may correspond to blocks 912, 914, and 916 as previously discussed in FIG. 9. The cluster tools minimize air exposure, which tends to minimize nitrogen atom loss from the STI liner surface prior to the following N₂O oxidation.

Referring now to FIG. 12A, one can see one embodiment of a cluster tool 1200 that includes a load lock module 1202, a plasma (non-thermal) module 1204, and a thermal oxidation module 1206 that may also perform an anneal (e.g., FIG. 9 anneal 918). The modules are separated from one another by isolation gates. In order to suitably process a wafer 1208, the wafer 1208 can first be inserted into the load-lock module 1202, wherein the load-lock module has an inner chamber that is environmentally isolated from the atmosphere outside of the cluster tool 1200. After the wafer 1208 has been inserted into the loadlock module 1202, the isolation gate 1210 can be closed and the loadlock module can, for example, be pumped down to a low pressure. Next, the isolation gate 1210 can be opened, and the wafer can be moved into the plasma module 1204. At this point isolation gates 1210 and 1212 can be closed, and plasma nitridation can be carried out as previously discussed. Next, the isolation gate 1210 can be opened, and the wafer can be placed in the thermal oxidation module 1206. Again, the isolation gate 1210 is closed and now an oxidation process can be performed to form a nitrogen containing liner. After the nitrogen containing liner is formed, the wafer can be suitably removed from the cluster tool, for example, by way of the plasma module 1204 and the load-lock module 1206, respectively.

Referring now to FIG. 12B, one can see another embodiment of a cluster tool 1214 that includes a first load lock module 1216, a plasma (non-thermal) module 1218, a thermal oxidation module 1220, and a second load lock module 1222. Again, the modules are separated from one another by isolation gates. In this embodiment, a wafer 1224 can first be inserted into the first load-lock module 1216, then proceed to the plasma (non-thermal) module 1218. After plasma nitridation is carried out on the wafer in the plasma module 1218, the wafer can then be moved to the thermal oxidation module 1220, where oxidation can take place. After the wafer has been oxidized, it will proceed to load-lock module 1222, after which it can be removed from the cluster tool 1214.

Referring now to FIG. 12C, one can see yet another embodiment of a cluster tool 1226 that includes a load lock module 1228, a transfer module 1230, a plasma (non-thermal) module 1232, and a thermal oxidation module 1234. Again, the modules are separated from one another by isolation gates. In this embodiment, a wafer 1236 can first be inserted into the load-lock module 1228, then proceed to the transfer module 1230, which can for example be pumped down to low-pressure. From the transfer module, the wafer can be moved to the plasma (non-thermal) module 1232, where plasma nitridation is carried out. Next, the wafer can be moved back through the transfer module 1230 to the thermal oxidation module 1234, where oxidation can take place. After the wafer has been oxidized, it will proceed back through the transfer module 1230 and load-lock module 1228, after which it can be removed from the cluster tool 1214.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

What is claimed is:

1. A cluster tool for semiconductor processing, comprising:
a plasma module configured to form a nitrided surface on a wafer by performing a plasma nitridation of an isolation trench; and
a thermal oxidation module configured to perform an oxidation of the nitrided surface;
wherein the wafer is transferred between the plasma module and the thermal oxidation module in a manner that limits the exposure of the wafer to environmental conditions outside of the cluster tool.

2. The cluster tool of claim 1, wherein the thermal oxidation tool is further configured to perform an anneal.

3. The cluster tool of claim 1 wherein the plasma module and the thermal oxidation module are adjacent to one another, and further comprising:
an isolation gate disposed between the plasma module and the thermal oxidation module.

4. The cluster tool of claim 3, further comprising:
a load-lock module configured to receive the wafer and thereby isolate the wafer from environmental conditions outside of the cluster tool.

5. The cluster tool of claim 1, further comprising:
a transfer module disposed between the plasma module and the thermal oxidation module, wherein the transfer module has a low pressure environment therein.

6. The cluster tool of claim 5, further comprising:
a load-lock module configured to receive the wafer and thereby isolate the wafer from environmental conditions outside of the cluster tool.

7. A method of forming a semiconductor device having isolation structures, the method comprising:
forming trench regions within a semiconductor body;
nitriding surfaces of the trench regions;
subjecting the nitrided surfaces to a condition that limits nitrogen desorption from the nitrided surfaces;
oxidizing the nitrided surfaces of the trench regions to form nitrogen containing liners; and
filling the isolation trench with a dielectric material.

8. The method of claim 7, wherein the condition is an environmental condition.

9. The method of claim 8, wherein the environmental condition is a low vacuum environmental condition.

10. The method of claim 8, wherein the environmental condition is a high vacuum environmental condition.

11. The method of claim 8, wherein the environmental condition is a low oxygen environmental condition.

12. The method of claim 8, wherein the environmental condition is a high nitrogen environmental condition.

13. The method of claim 7, wherein the following acts are carried out in a cluster tool: nitriding surfaces of the trench regions, subjecting the nitrided surfaces to a condition that limits nitrogen desorption from the nitrided surfaces, and oxidizing the nitrided surfaces of the trench regions to form nitrogen containing liners.

14. The method of claim 7, wherein forming trench regions within isolation regions comprises forming a resist mask that exposes the isolation regions and etching the exposed regions for a selected time to form the trench regions with a bottom and sidewalls.

15. The method of claim 7, wherein forming trench regions within isolation regions comprises forming a hard mask that exposes the isolation regions and etching the exposed regions to form the trench regions with a bottom and sidewalls.

16. The method of claim 15, wherein the hard mask is comprised of silicon nitride.

17. The method of claim 7, wherein nitriding surfaces of the trench regions comprises performing a plasma based nitridation process.

18. The method of claim 17, wherein the plasma nitridation process is performed for a duration selected to obtain a desired nitrogen concentration at liner/substrate interfaces.

19. The method of claim 7, wherein oxidizing the nitrided surfaces comprises performing a thermal growth process that forms the nitrogen containing liners.

20. A method of forming an isolation structure, comprising:
forming a pad oxide layer over a semiconductor body;
forming a hard mask layer on the pad oxide layer;
forming a resist mask on the hard mask layer that exposes the hard mask layer within the isolation regions and covers the hard mask layer within active regions of the device;
patterning the hard mask layer to expose the semiconductor body within the isolation regions;
performing an etch process using the hard mask layer as a mask that forms trench regions within the isolation regions;
nitriding exposed surfaces of the trench regions;
subjecting the nitrided surfaces to a condition that limits nitrogen desorption from the nitrided surfaces;
oxidizing the exposed surfaces of the trench regions to form nitrogen containing layers; and
filling the isolation trench with a dielectric material.
